(19) United States
(12) Patent Application Publication
(10) Pub. No.: US 2007/0111025 A1
(43) Pub. Date: May 17, 2007

(54) Use of platinum ll complexes as luminescent materials in organic light-emitting diodes (oleds)

(75) Inventors: Christian Lennartz, Neuhofen (DE); Arnd Vogler, Regensburg (DE); Valeri Pawlowski, Regenburg (DE)

Correspondence Address: OBLON, SPIVAK, MCCLELLAND, MAIER & NEUSTADT, P.C., 1940 DUKE STREET, ALEXANDRIA, VA, 22314, US

(73) Assignee: BASF Aktiengesellschaft, Ludwigshafen (DE)

(21) Appl. No.: 10/580,836

(22) PCT Filed: Dec. 8, 2004
(86) PCT No.: PCT/EP04/13944

§ 371 Date: May 26, 2006

(30) Foreign Application Priority Data
Dec. 12, 2003 (DE) 1038665.2

(51) Int. Cl. H01L 51/54; C09K 11/06

(52) U.S. Cl. 428/690; 252/301.16; 313/504; 428/917; 257/E51.044; 546/2; 546/10; 556/19; 556/21

(57) ABSTRACT

The present invention relates to the use of platinum(II) complexes of the formulae I, II and III as emitter molecules in organic light-emitting diodes (OLEDs), 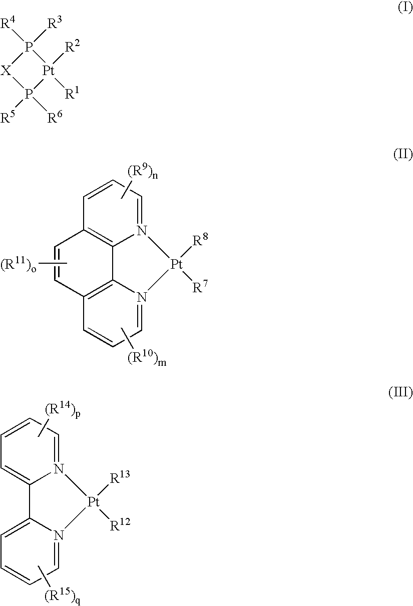 where the radicals are defined in the claims and in the description. Furthermore, the present invention relates to the use of the platinum(II) complexes as light-emitting layer in OLEDs, a light-emitting layer comprising at least one platinum(II) complex, an OLED comprising this light-emitting layer and devices comprising an OLED according to the invention.

The present invention relates to the use of platinum(II) complexes as emitter molecules in organic light-emitting diodes (OLEDs), the use of the platinum(II) complexes as light-emitting layer in OLEDs, a light-emitting layer comprising at least one platinum(II) complex, an OLED comprising this light-emitting layer and also devices in which an OLED according to the invention is present.

Organic light-emitting diodes (OLEDs) exploit the ability of materials to emit light when they are excited by means of an electric current. OLEDs are particularly interesting as alternatives to cathode ray tubes and liquid crystal displays for producing flat VDUs. Owing to their very compact construction and their intrinsically lower power consumption, devices comprising OLEDs are particularly suitable for mobile applications, for example for applications in mobile telephones, laptops, etc.

Numerous materials which emit light on excitation by means of an electric current have been proposed.

WO 02/15645 relates to OLEDs which have a light-emitting layer comprising phosphorescent transition metal compounds as dopants. The transition metal compounds, including acetylacetonatoplatinum complexes, display electrophosphorescence.

WO 01/41512 relates to OLEDs which have a light-emitting layer comprising a molecule of the general formula L₂MX, where M is particularly preferably iridium and L is selected from the group consisting of 2-(1-naphthyl)benzoxazole, 2-phenylbenzoxazole, 2-phenylbenzothiazole, 7,8-benzoquinoline, coumarin, thienylpyridine, phenylpyridine, benzothienylpyridine, 3-methoxy-2-phenylpyridine and tolylpyridine and X is selected from the group consisting of acetylacetonate, hexafluoroacetylacetonate, salicylidene, picolinate and 8-hydroxyquinolinate. According to the description, the molecules of the formula L₂MX can be used as dopants or in bulk in the light-emitting layer. In the examples, however, a molecule of the formula L₂MX (bis(2-phenylbenzothiazole)iridium acetylacetonate (“BTIr”)) is used only as dopant.

WO 00/70655 relates to electroluminescent layers comprising a phosphorescent organometallic iridium compound or osmium compound as light-emitting substance. Preference is given to using tris(2-phenylpyridine)iridium (Ir(ppy)₃) as light-emitting compound. Ir(ppy)₃ can be used in bulk or as dopant in 4,4′-N,N′-dicarbazolylbiphenyl (CBP) as host substance. According to the examples (Example 2), the use of Ir(ppy)₃ in bulk is found to result in a pronounced reduction in the efficiency of the OLEDs compared to its use as dopant.

Although compounds which display electroluminescence in the blue, red and green regions of the electromagnetic spectrum are already known, the provision of further compounds which can also be used in bulk as light-emitting layer is desirable. For the purposes of the present invention, the term electroluminescence encompasses both electrofluorescence and electrofluosphorescence.

It is therefore an object of the present application to provide a class of compounds which is capable of electroluminescence in the blue, red and green regions of the electromagnetic spectrum, thus making the production of full-color displays possible. A further object of the present application is to provide compounds which can be used in bulk, without host substances, as light-emitting layer in OLEDs.

This object is achieved by the use of uncharged platinum(II) complexes selected from the group consisting of
platinum(II)-phosphine complexes of the formula (I), 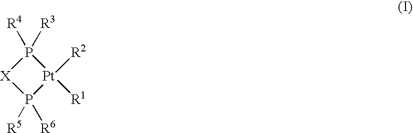
platinum(II)-bathophen complexes of the formula (II) 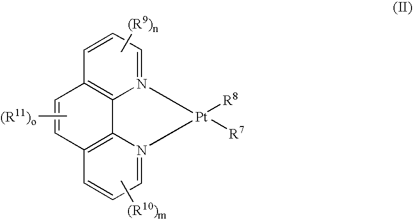
and
platinum(II)-bipyridyl complexes of the formula (III) 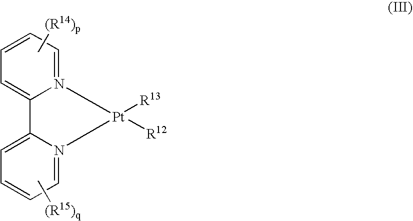
where the symbols have the following meanings:
R¹, R², R⁷, R⁸, R¹², R¹³ are each, independently of one another, CN, acetylide, thiocyanate or isocyanate, preferably CN or acetylide, with both acetylides bearing alkyl radicals, in particular t-butyl radicals, and acetylides bearing aromatic radicals being suitable; particularly preferably CN;
R³, R⁴, R⁵, R⁶, R⁹, R¹⁰, R¹⁴, R¹⁵ are each, independently of one another, an aryl, alkyl, heteroaryl or alkenyl group, preferably an aryl or alkyl group;
X is an arylene group or a heteroarylene group;
o is from 0 to 2, preferably 0;
p, q are each, independently of one another, from 0 to 4, preferably 0 or 1, with the groups R¹⁴ and R¹⁵ particularly preferably being in the 4 and 7 positions of the bipyridyl ligand when p and q are each 1;
n, m are each, independently of one another, from 0 to 3, preferably 0 or 1, with the groups R⁹ and R¹⁰ particularly preferably being in the 4 and 7 positions of the bathophen ligand when n and m are each 1,
   where, when m, n, o, p and/or q are 0, the corresponding parts of the bathophen or bipyridyl ligands bear hydrogen atoms, i.e. are unsubstituted,
   as emitter molecules in organic light-emitting diodes.

Platinum(II) complexes are known in the prior art. Thus, Vogler, J. Am. Chem. Soc. 1990, 112, 5625 to 5627, discloses the complex Pt(bathophen)(CN)₂ (bathophen=4,7-diphenyl-1,10-phenanthroline). No information is given regarding the electroluminescence of this Pt complex.

Yam et al. Coordination Chemistry Reviews 229 (2002), 123 to 132, concerns luminescence studies on binuclear platinum(II)-alkynyl complexes and the corresponding mixed metal platinum(II)-copper(1) and platinum(II)-silver(I) complexes. The platinum(II) complexes examined are binuclear complexes. A red shift of the binuclear complexes compared to a mononuclear complex which was likewise studied, trans-[Pt(dppm-P)₂(C≡CR)₂], was observed.

In Crosby et al. Coordination Chemistry Reviews 171 (1998), 407 to 417, the characteristics of electronically excited states of transition metal complexes are examined. The studies were carried out on the complexes Pt(2,2′-bipyridine)(CN)₂ and Pt(2,2′-bipyridine)Cl₂, which in their solid state form linear chains, and on Pt(2-phenylpyridine)₂, which crystallizes in discrete dimeric units.

Che et al. Inorg. Chem. 2002, 41, 3866 to 3875, is concerned with metal-metal interactions in binuclear d⁸-metal cyanide complexes bearing phosphine ligands. Complexes examined are trans-[M₂(μ-diphosphine)₂(CN)₄] and trans-[M(phosphine)₂(CN)₂], where M is Pt or Ni. According to Table 3, page 3871, the mononuclear complex [Pt(PCy₃)₂(CN)₂] does not emit light in dichloromethane.

None of the abovementioned documents is concerned with the electroluminescence of the complexes disclosed therein, on which the use of compounds as emitter substances in OLEDs is based.

The suitability of platinum(II) complexes of the formulae I, II and III according to the present invention as light-emitting substances in OLEDs, with the substances of this structural type of the formula I, II or III being capable of electroluminescence in the red, green and blue regions of the electromagnetic spectrum, is thus mentioned in none of the abovementioned documents.

It has therefore been found that the platinum(II) complexes of the formulae I, II and III according to the present patent application are useful as light-emitting substances in OLEDs for producing full-color displays.

For the purposes of the present application, the terms aryl radical or group, heteroaryl radical or group, alkyl radical or group, alkenyl radical or group, arylene radical or group and heteroarylene radical or group have the following meanings:

An aryl radical (or group) is a radical which has a basic framework of from 6 to 30 carbon atoms, preferably from 6 to 18 carbon atoms, and is made up of an aromatic ring or a plurality of fused aromatic rings. Suitable basic frameworks are, for example, phenyl, naphthyl, anthracenyl and phenanthrenyl. This basic framework can be unsubstituted (i.e. all carbon atoms which are capable of substitution bear hydrogen atoms) or be substituted on one, more than one or all substitutable positions of the basic framework. Suitable substituents are, for example, alkyl radicals, preferably alkyl radicals having from 1 to 8 carbon atoms, particularly preferably methyl, ethyl, i-propyl or t-butyl, aryl radicals, preferably C₆-aryl radicals, which may once again be substituted or unsubstituted, heteroaryl radicals, preferably heteroaryl radicals containing at least one nitrogen atom, particularly preferably pyridyl radicals, alkenyl radicals, preferably alkenyl radicals which have one double bond, particularly preferably alkenyl radicals having a double bond and from 1 to 8 carbon atoms, or groups having a donor or acceptor action. For the purposes of the present invention, groups having a donor action are groups which display a +1 and/or +M effect, and groups having an acceptor action are groups which display a −I and/or −M effect. Suitable groups having a donor or acceptor action are halogen radicals, preferably F, Cl, Br, particularly preferably F, alkoxy radicals, carbonyl radicals, ester radicals, amine radicals, amide radicals, CH₂F groups, CHF₂ groups, CF₃ groups, CN groups, thio groups or SCN groups. The aryl radicals very particularly preferably bear substituents selected from the group consisting of methyl, F, Cl and alkoxy, or the aryl radicals are unsubstituted. Preference is given to the aryl radical or the aryl group being a C₆-aryl radical which may optionally be substituted by at least one of the abovementioned substituents. The C₆-aryl radical particularly preferably bears none, one or two of the abovementioned substituents, with the one substituent preferably being located in the para position relative to the further linkage point of the aryl radical and, in the case of two substituents, these are each located in the meta position relative to the further linkage point of the aryl radical. The C₆-aryl radical is very particularly preferably an unsubstituted phenyl radical.

A heteroaryl radical or a heteroaryl group is a radical which differs from the abovementioned aryl radicals in that at least one carbon atom in the basic framework of the aryl radical is replaced by a heteroatom. Preferred heteroatoms are N, O and S. Very particular preference is given to one or two carbon atoms of the basic framework of the aryl radical being replaced by heteroatoms. The basic framework is particularly preferably selected from among electron-rich systems such as pyridyl, cyclic esters, cyclic amides and five-membered heteroaromatics such as pyrrole, furans. The basic framework can be substituted on one, more than one or all substitutable positions of the basic framework. Suitable substituents are the same as those mentioned above in respect of the aryl groups.

An alkyl radical or alkyl group is a radical having from 1 to 20 carbon atoms, preferably from 1 to 10 carbon atoms, particularly preferably from 1 to 8 carbon atoms. This alkyl radical can be branched or unbranched and may be interrupted by one or more heteroatoms, preferably N, O or S. Furthermore, this alkyl radical may be substituted by one or more of the substituents mentioned in respect of the aryl groups. It is likewise possible for the alkyl radical to bear one or more aryl groups. All the abovementioned aryl groups are suitable for this purpose. The alkyl radicals are particularly preferably selected from the group consisting of methyl, ethyl, i-propyl, n-propyl, i-butyl, n-butyl, t-butyl, sec-butyl, i-pentyl, n-pentyl, sec-pentyl, neopentyl, n-hexyl, i-hexyl and sec-hexyl. Very particular preference is given to methyl, i-propyl and n-hexyl.

An alkenyl radical or an alkenyl group is a radical which corresponds to the abovementioned alkyl radicals having at least two carbon atoms, except that at least one C—C single bond of the alkyl radical is replaced by a C—C double bond. The alkenyl radical preferably has one or two double bonds.

An arylene group or an arylene radical is a group having from 6 to 60 carbon atoms, preferably from 6 to 20 carbon atoms. Suitable groups are, for example, phenylene groups, preferably phenylene groups which are linked in the 1 and 2 positions to, in each case, one of the P atoms in the formula I, naphthalenediyl groups, preferably naphthalenediyl groups which are linked in the 2 and 3 positions or in the 4 and 5 positions to, in each case, one of the two P atoms in the formula I, anthracenediyl groups, preferably anthracenediyl groups which are linked in the 2 and 3 positions or 4 and 10 positions or 4 and 5 positions to, in each case, one of the two P atoms in the formula I, phenanthrenediyl groups, preferably phenanthrenediyl groups which are linked in the 2 and 3 positions or in the 4 and 5 positions to, in each case, one of the two P atoms in the formula I, biphenylene groups, preferably 1,1′-biphenylene, particularly preferably 1,1′-biphenylene groups which are linked in the 2 and 2′ positions to, in each case, one of the two P atoms in the formula I, binaphthylene groups, preferably 1,1′-binaphthylene groups, particularly preferably 1,1′-binaphthylene groups which are linked in the 2 and 2′ positions to, in each case, one of the two P atoms in the formula I, xanthylene groups, preferably xanthylene groups which are linked in the 4 and 5 positions to, in each case, one of the two P atoms in the formula I, particularly preferably xanthylene groups which bear H or a methyl group in each of the 9 and 9′ positions. Furthermore, triphenylene groups, stilbenediyl groups, distilbenediyl groups and further groups containing fused rings, preferably fused 6-membered rings, are also suitable as arylene groups.

The abovementioned arylene groups or radicals can be unsubstituted or substituted. Suitable substituents are, for example, alkyl radicals, preferably alkyl radicals having from 1 to 8 carbon atoms, particularly preferably methyl, ethyl, i-propyl or t-butyl, aryl radicals, preferably C₆ aryl radicals which may in turn be substituted or unsubstituted, heteroaryl radicals, preferably heteroaryl radicals containing at least one nitrogen atom, particularly preferably pyridyl radicals, alkenyl radicals, preferably alkenyl radicals having one double bond, particularly preferably alkenyl radicals having one double bond and from 1 to 8 carbon atoms, or groups having a donor or acceptor action. For the purposes of the present invention, groups having a donor action are groups which display a +1 and/or +M effect, and groups having an acceptor action are groups which display a −I and/or −M effect. Suitable groups having a donor or acceptor action are halogen radicals, preferably F, Cl, Br, particularly preferably F, alkoxy radicals, carbonyl radicals, ester radicals, amine radicals, amide radicals, CH₂F groups, CHF₂ groups, CF₃ groups, CN groups, thio groups or SCN groups. The arylene radicals very particularly preferably bear substituents selected from the group consisting of methyl, F, Cl and alkoxy. The appropriate number of possible substituents depends on the particular compound and is known to those skilled in the art. The abovementioned compounds are preferably unsubstituted or bear one or two substituents. Very particular preference is given to the abovementioned compounds being unsubstituted. Preferred arylene groups or radicals are selected from the group consisting of phenylene groups which are linked in the 1 and 2 positions to, in each case, one of the P atoms in the formula I and are particularly preferably unsubstituted, naphthalenediyl groups which are linked in the 2 and 3 positions or in the 4 and 5 positions to, in each case, one of the P atoms in the formula I and are particularly preferably unsubstituted, and 1,1′-binaphthylene groups which are linked in the 2 and 2′ positions to, in each case, one of the P atoms in the formula I and are particularly preferably unsubstituted.

Suitable heteroarylene groups are ones in which at least one CH unit of the abovementioned compounds has been replaced by a unit comprising a heteroatom which is preferably selected from among oxygen, sulfur, nitrogen, phosphorus and boron, particularly preferably oxygen, sulfur and nitrogen, very particularly preferably nitrogen. Preference is given to one or two CH groups of the abovementioned compounds being replaced by one of the abovementioned heteroatoms.

Suitable heteroarylene groups containing nitrogen as heteroatom are pyridinediyl groups, diazaphenylene groups, quinolinediyl groups, quinoxalinediyl groups, aziridinediyl groups, bipyridyl groups, phenanthrolinediyl groups, where in each case linkage to, in each case, one of the two P atoms in the formula I is possible. Suitable groups which contain heteroatoms other than nitrogen atoms are known to those skilled in the art. The heteroarylene groups can be unsubstituted or substituted, with the number of substituents depending on the respective heteroarylene group. Suitable substituents are the same as those mentioned above in respect of the arylene radicals. In one embodiment, the heteroarylene groups are unsubstituted or bear one or two substituents. The heteroarylene groups are very particularly preferably unsubstituted.

Preferred platinum(II) complexes of the formula I are those in which R¹ and R² are each CN or acetylide, particularly preferably CN, and R³, R⁴, R⁵ and R⁶ are each an aryl radical, preferably a phenyl radical which may be substituted as mentioned above or be unsubstituted, particularly preferably an unsubstituted phenyl radical, and X is selected from the group consisting of a phenylene group which is linked in the 1 and 2 positions to, in each case, one of the two P atoms in the formula I and is particularly preferably unsubstituted, a naphthalenediyl group which is linked in the 2 and 3 positions or 4 and 5 positions to, in each case, one of the two P atoms in the formula I and is particularly preferably unsubstituted, a phenanthrenediyl group which is linked in the 2 and 3 positions or in the 4 and 5 positions to, in each case, one of the two P atoms in the formula I and the phenanthrenylene group is particularly preferably unsubstituted, a 1,1′-biphenylene group which is linked in the 2 and 2′ positions to, in each case, one of the two P atoms in the formula I and is particularly preferably unsubstituted, and a 1,1′-binaphthylene group which is linked in the 2 and 2′ positions to, in each case, one of the two P atoms in the formula I and is particularly preferably unsubstituted. X is particularly preferably selected from among an unsubstituted phenylene group which is linked in the 1 and 2 positions to, in each case, one of the two P atoms in the formula I and a 1,1′-binaphthylene group which is linked in the 2 and 2′ positions to, in each case, one of the two P atoms in the formula I and is unsubstituted.

Preferred platinum(II)-bathophen complexes of the formula II are those in which R⁷ and R⁸ are each acetylide or CN, particularly preferably CN, and m, n and o are each 0 or 1, with the bathophen group being unsubstituted when o=0 and the bathophen group being substituted by the abovementioned substituents when m, n and o are, independently of one another, 1, and the substituents R⁹, R¹⁰ and R¹¹ of the bathophen group of the formula (II) particularly preferably being unsubstituted phenyl. Very particular preference is given to m, n and o=0 or o being 0 and m and n each being 1, and very particular preference being given to R⁹ and R¹⁰ each being unsubstituted phenyl. The substituents R⁹ and R¹⁰ are especially preferably located in the 4 and 7 positions of the bathophen radical when m and n are each 1.

The platinum(II)-bipyridyl complex of the formula III is preferably a complex in which R¹² and R¹³ are each acetylide or CN, preferably CN, and p and q are each 0 or 1, with preference being given to both p and q being 0 or both p and q being 1. When p and q are each 1, R¹⁴ and R¹⁵ are substituents as defined above. Very particular preference is given to R¹⁴ and R¹⁵ being tert-butyl. The substituents R¹⁴ and R¹⁵ are especially preferably located in the 4 and 7 positions of the bipyridyl radical when p and q=1.

The present patent application further provides for the use of Pt(II) complexes of the formulae II and III in which R⁷, R⁸, R¹² and R¹³ are each CN, m, n, p, q are each 0 or 1 and o is 0, and, when m, n=1, R⁹ and R¹⁰ are each unsubstituted phenyl and, when p, q=1, R¹⁴ and R¹⁵ are each tert-Bu.

Very particularly preferred compounds of the formulae I, II and III are those of the following formulae

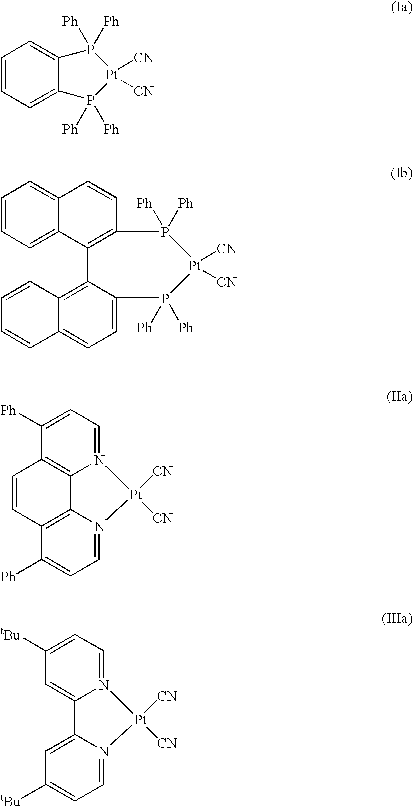

The abovementioned uncharged transition metal complexes are highly suitable as emitter molecules in organic light-emitting diodes (OLEDs). A simple variation of the ligands makes it possible to provide transition metal complexes which display electroluminescence in the red, green and in particular blue regions of the electromagnetic spectrum. The uncharged transition metal complexes used according to the invention are therefore suitable for use in industrially usable full-color displays.

The platinum(II) complexes are prepared by methods known to those skilled in the art.

Customary methods are, for example, deprotonation of the ligand precursors corresponding to the ligands of the compounds of the formulae II, II and III and subsequent reaction, generally in situ, with suitable Pt-containing metal complexes. The platinum(II) complexes of the formulae II, II and III can also be prepared by direct reaction of the uncharged ligand precursors corresponding to the ligands of the platinum(II) complexes with appropriate platinum(II) complexes, which is preferred.

Suitable ligand precursors which lead to the ligands of the platinum(II) complexes of the formulae I, II and III are known to those skilled in the art.

If deprotonation of the ligands is carried out, this can be achieved by means of basic metallates, basic anions such as metal acetates, acetylacetonates or alkoxides or external bases such as KO^{t}Bu, NaO^{t}Bu, LiO^{t}Bu, NaH, silylamides and phosphazene bases.

Platinum complexes which are suitable as starting compound are known to those skilled in the art and preferably contain radicals of the groups R¹ and R², or R⁷ and R⁸ or R¹² and R¹³. Preferred platinum complexes are thus platinum-acetylide complexes and platinum-cyanide complexes such as Pt(CN)₂. The platinum-acetylide complexes can be obtained by, for example, reacting the corresponding platinum chloride complex, e.g. [Pt(dppm)₂]Cl₂, with an acetylide, e.g. Li acetylide or mercury acetylide. Suitable methods of preparing platinum acetylides are disclosed in Yam et al. Coordination Chemistry Reviews 229 (2002) 123-132, and the literature cited therein.

The reaction is preferably carried out in a solvent. Suitable solvents are known to those skilled in the art and are preferably selected from among aromatic, aliphatic solvents, ethers, alcohols and polar aprotic solvents. Particularly useful polar aprotic solvents are dimethylformamide and dimethylacetamide.

The molar ratio of platinum complex used to ligand precursor used is preferably from 0.7:1.0 to 1.5:1.0, particularly preferably from 0.9:1.0 to 1.1:1, very particularly preferably 1:1.

The platinum(II) complexes of the formulae I, II and III are preferably obtained by direct reaction of the appropriate ligand precursor with a platinum complex. This reaction is particularly preferably carried out a polar aprotic solvent in the abovementioned molar ratios of platinum complexes to ligand precursors used.

The reaction is generally carried out at temperatures of from 20 to 200° C., preferably from 70 to 180° C., particularly preferably at the boiling point of the solvent used.

The reaction time depends on the desired platinum(II) complex and is generally from 1 hour to 50 hours, preferably from 2 hours to 30 hours, particularly preferably from 5 hours to 25 hours.

The platinum(II) complex of the formula I, II or III obtained is worked up by methods known to those skilled in the art. For example, the product which has precipitated during the reaction is filtered off, washed, for example with ether, in particular diethyl ether, and subsequently dried. Recrystallization, for example from dichloromethane/diethyl ether or dichloroethane/diethyl ether, gives highly pure platinum(II) complexes.

The platinum(II) complexes of the formulae (I), (II) and (III) which are used according to the invention are very useful as emitter substances since they display emission (electroluminescence) in the visible region of the electromagnetic spectrum. The use of the platinum(II) complexes employed according to the invention as emitter substances makes it possible to provide compounds which display electroluminescence in the red, green and blue regions of the electromagnetic spectrum. Use of the platinum(II) complexes employed according to the invention as emitter substances thus makes it possible to provide industrially usable full-color displays.

The platinum(II) complexes, in particular the platinum(II) complexes of the formula I, are preferably mononuclear complexes. These are preferably not only mononunclear in solution, but also in the solid state. The present patent application therefore further provides for the use of platinum(II) complexes of the formulae I, II and III, with platinum(II) complexes of the formula I being particularly preferred, which are mononuclear complexes. Particularly preferred mononuclear complexes are the platinum(II) complexes which have been referred to above as being particularly preferred.

A particular property of the platinum(II) complexes of the formulae I, II and III is that in the solid state they display luminescence, particularly preferably electroluminescence, in the visible region of the electromagnetic spectrum. These complexes which display luminescence in the solid state, can be used as such, i.e. without further additives, as emitter substances in OLEDs. In this way, it is possible to produce an OLED having a light-emitting layer without any complicated codeposition of a matrix material with the emitter substance being necessary. Mononuclear platinum(II) complexes which display luminescence, in particular electroluminescence, in the solid state are not known from the prior art.

The present patent application therefore also provides for the use of platinum(II) complexes of the formulae I, II and III, particularly preferably platinum(II) complexes of the formula I, as light-emitting layer in OLEDs.

Organic light-emitting diodes are basically made up of a plurality of layers:

1. Anode

2. Hole-transporting layer

3. Light-emitting layer

4. Electron-transporting layer

5. Cathode

The platinum(II) complexes of the formulae I, II and III, preferably the complexes of the formula I, are preferably used as emitter molecules in the light-emitting layer. The present application therefore also provides a light-emitting layer comprising at least one platinum(II) complex of the formulae I, II and/or III, preferably at least one complex of the formula I, as emitter molecule. Preferred platinum(II) complexes of the formulae I, II and III, in particular platinum(II) complexes of the formula I, have been mentioned above.

The platinum(II) complexes of the formulae I, II and III which are used according to the invention can be present as such, without further additives, in the light-emitting layer. However, it is also possible for further compounds to be present in the light-emitting layer in addition to the platinum(II) complexes of the formulae I, II and III which are used according to the invention. For example, a fluorescent dye can be present to alter the color of the emission of the platinum(II) complex used as emitter molecule. Furthermore, a diluent material can be used. This diluent material can be a polymer, for example a poly(N-vinylcarbazole) or polysilane. However, the diluent material can likewise be a small molecule, for example 4,4′-N,N′-dicarbazolylbiphenyl (CDP) or a tertiary aromatic amine. If a diluent material is used, the proportion of the platinum(II) complexes used according to the invention in the light-emitting layer is generally less than 20% by weight, preferably from 3 to 10% by weight. The platinum(II) complexes of the formulae I, II and III are preferably used as such, so that complicated covaporization of the platinum(II) complexes with a matrix material (diluent material or fluorescent dye) is avoided. To achieve this, it is important that the platinum(II) complexes luminesce in the solid state. The platinum(II) complexes of the formulae I, II and III display luminescence in the solid state. Thus, the light-emitting layer preferably comprises at least one platinum(II) complex of the formula I, II or III, preferably a platinum(II) complex of the formula I, and no matrix material selected from among diluent material and fluorescent dye.

In a preferred embodiment, the present application also provides a light-emitting layer consisting of at least one platinum(II) complex of the formulae I, II and/or III, preferably consisting of at least one complex of the formula I, as emitter molecule. Preferred complexes of the formulae I, II and III have been mentioned above.

The individual layers mentioned above of the OLED can in turn be made up of 2 or more layers. For example, the hole-transporting layer can be made up of a layer into which holes are injected from the electrode and a layer which transports the holes away from the hole-injecting layer into the light-emitting layer. The electron-transporting layer can likewise consist of a plurality of layers, for example a layer into which electrons are injected by the electrode and a layer which receives electrons from the electron-injecting layer and transports them into the light-emitting layer. These layers are in each case selected according to factors such as energy level, heat resistance and charge carrier mobility, and also energy difference between the layers mentioned and the organic layers or the metal electrodes. A person skilled in the art is able to choose the structure of the OLEDs so that it is optimally matched to the platinum(II) complexes used according to the invention as emitter substances.

To obtain particularly efficient OLEDs, the HOMO (highest occupied molecular orbital) of the hole-transporting layer should be matched to the work function of the anode and the LUMO (lowest unoccupied molecular orbital) of the electron-transporting layer should be matched to the work function of the cathode.

The present application also provides an OLED comprising at least one light-emitting layer according to the invention. The further layers in the OLED can be made up of any material which is customarily used in such layers and is known to those skilled in the art.

The anode (1) is an electrode which provides positive charge carriers. It can be made up of, for example, materials which comprise a metal, a mixture of various metals, a metal alloy, a metal oxide or a mixture of various metal oxides. As an alternative, the anode can be a conductive polymer. Suitable metals include the metals of groups 11, 4, 5 and 6 of the Periodic Table of the Elements and the transition metals of groups 8 to 10. If the anode is to allow light to pass through it, use is generally made of mixed metal oxides of groups 12, 13 and 14 of the Periodic Table of the Elements, for example indium-tin oxide (ITO). It is likewise possible for the anode (1) to comprise an organic material, for example polyaniline, as described, for example, in Nature, Vol. 357, pages 477 to 479 (Jun. 11, 1992). At least one of the anode and cathode should be at least partially transparent to enable the light generated to be radiated.

Suitable hole transport materials for the layer (2) of the OLED of the invention are disclosed, for example, in Kirk-Othmer Encyclopedia of Chemical Technologie, 4^{th} Edition, Vol. 18, pages 837 to 860, 1996. Both hole-transporting molecules and polymers can be used as hole transport material. Hole-transporting molecules usually used are selected from the group consisting of 4,4′-bis[N-(1-naphthyl)-N-phenylamino]biphenyl (α-NPD), N,N′-diphenyl-N,N′-bis(3-methylphenyl)[1,1′-biphenyl]-4,4′-diamine (TPD), 1,1-bis[(di-4-tolylamino)phenyl]cyclohexane (TAPC), N,N′-bis(4-methylphenyl)-N,N′-bis(4-ethylphenyl)-[1,1′-(3,3′-dimethyl)biphenyl]-4,4′-diamine (ETPD), tetrakis(3-methylphenyl)-N,N,N′,N′-2,5-phenylenediamine (PDA), α-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl)(4-methylphenyl)methane (MPMP), 1-phenyl-3-[p-(diethylamino)styryl]-5-[p-(diethylamino)phenyl]pyrazoline (PPR or DEASP), 1,2-trans-bis(9H-carbazol-9-yl)cyclobutane (DCZB), N,N,N′,N′-tetrakis(4-methylphenyl)(1,1′-biphenyl)-4,4′-diamine (TTB) and porphyrin compounds such as copper phthalocyanines. Customarily used hole-transporting polymers are selected from the group consisting of polyvinylcarbazoles, (phenylmethyl)polysilanes and polyanilines. It is likewise possible to obtain hole-transporting polymers by doping polymers such as polystyrene and polycarbonate with hole-transporting molecules. Suitable hole-transporting molecules are the molecules mentioned above.

Suitable electron-transporting materials for the layer (4) of the OLEDs of the invention encompass metals chelated by oxynoid compounds, e.g. tris(8-hydroxy-quinolato)aluminum (Alq₃), compounds based on phenanthroline, e.g. 2,9-dimethyl-4,7-diphenyl-1,10-phenanthroline (DDPA) or 4,7-diphenyl-1,10-phenanthroline (DPA) and azole compounds such as 2-(4-biphenylyl)-5-(4-t-butylphenyl)-1,3,4-oxadiazole (PBD) and 3-(4-biphenylyl)-4-phenyl-5-(4-t-butylphenyl)-1,2,4-triazole (TAZ). Here, the layer (4) can serve both to aid electron transport and to act as a buffer layer or barrier layer to avoid quenching of the exciton at the interfaces of the layers of the OLED. The layer (4) preferably improves the mobility of the electrons and reduces quenching of the exciton.

The cathode (5) is an electrode which serves to introduce electrons or negative charge carriers. The cathode can be any metal or non metal which has a work function lower than that of the anode. Suitable materials for the cathode are selected from the group consisting of alkali metals of group 1, for example Li, Cs, alkaline earth metals of group 2, metals of group 12 of the Periodic Table of the Elements encompassing the rare earth metals and the lanthanides and actinides. Furthermore, metals such as aluminum, indium, calcium, barium, samarium and magnesium and also combinations thereof can be used. It is also possible for lithium-containing organometallic compounds or LiF to be applied between the organic layer and the cathode in order to reduce the operating voltage.

The OLED of the present invention can further comprise additional layers which are known to those skilled in the art. For example, a layer which aids transport of the positive charge and/or matches the band gap of the layers to one another can be applied between the layer (2) and the light-emitting layer (3). As an alternative, this further layer can serve as protective layer. In an analogous fashion, additional layers can be present between the light-emitting layer (3) and the layer (4) in order to aid transport of the negative charge and/or to match the band gap of the layers to one another. As an alternative, this layer can serve as protective layer.

In a preferred embodiment, the OLED of the invention comprises, in addition to the layers (1) to (5), at least one of the additional layers mentioned in the following:
a hole injection layer between the anode (1) and the hole-transporting layer (2);
a blocking layer for electrons between the hole-transporting layer (2) and the light-emitting layer (3);
a blocking layer for holes between the light-emitting layer (3) and the electron-transporting layer (4);
an electron injection layer between the electron-transporting layer (4) and the cathode (5).

The person skilled in the art will know how to choose suitable materials (for example on the basis of electrochemical studies). Suitable materials for the individual layers are known to those skilled in the art and are disclosed, for example, in WO 00/70655.

Furthermore, each of the abovementioned layers of the OLED of the invention can be made up of two or more layers. Furthermore, it is possible for some or all of the layers (1), (2), (3), (4) and (5) to have been surface-treated in order to increase the efficiency of charge carrier transport. The choice of materials for each of the layers mentioned is preferably made in such a way that an OLED having a high efficiency is obtained.

The OLED of the invention can be produced by methods known to those skilled in the art. In general, the OLED is produced by successive vapor deposition of the individual layers on a suitable substrate. Suitable substrates include, for example, glass and polymer films. Vapor deposition can be carried out using customary techniques such as thermal vapor deposition, chemical vapor deposition and the like. In an alternative method, the organic layers can be applied by coating with solutions or dispersions in suitable solvents using coating techniques known to those skilled in the art.

In general, the various layers have the following thicknesses: anode (2) 500 to 5000 Å, preferably 1000 to 2000 Å; hole-transporting layer (3) 50 to 1000 Å, preferably 200 to 800 Å, light-emitting layer (4) 10 to 1000 Å, preferably 100 to 800 Å, electron-transporting layer (5) 50 to 1000 Å, preferably 200 to 800 Å, cathode (6) 200 to 10 000 Å, preferably 300 to 5000 Å. The position of the recombination zone of holes and electrons in the OLED of the invention and thus the emission spectrum of the OLED can be influenced by the relative thickness of each layer. This means that the thickness of the electron transport layer should preferably be selected so that the electron/hole recombination zone is located in the light-emitting layer. The ratio of the thicknesses of the individual layers in the OLED is dependent on the materials used. The thicknesses of any additional layers used are known to those skilled in the art.

The use of the platinum(II) complexes of the formulae I, II and III employed according to the invention as emitter molecule in the light-emitting layer of the OLEDs of the invention enables OLEDs having a high efficiency to be obtained. Furthermore, the efficiency of the OLEDs of the invention can be improved by optimizing the other layers. For example, highly efficient cathodes such as Ca, Ba or LiF can be used. Shaped substrates and new hole-transporting materials which effect a reduction in the operating voltage or an increase in the quantum efficiency can likewise be used in the OLEDs of the invention. Furthermore, additional layers can be present in the OLEDs in order to adjust the energy level of the various layers and to aid electroluminescence.

The OLEDs of the invention can be used in all devices in which electroluminescence is used. Suitable devices are preferably selected from among stationary and mobile VDUs. Stationary VDUs are, for example, VDUs of computers, televisions, VDUs in printers, kitchen appliances and advertising placards, lighting and information signs. Mobile VDUs are, for example, VDUs in mobile telephones, laptops, vehicles and destination displays in buses and trains.

Furthermore, the platinum(II) complexes of the formulae I, II and III used according to the invention can be used in OLEDs having an inverse structure. In these inverse OLEDs, the platinum(II) complexes are once again preferably used in the light-emitting layer, particularly preferably as light-emitting layer without further additives. The structure of inverse OLEDs and the materials customarily used therein are known to those skilled in the art.

### EXAMPLES

1. Preparation of Platinum(II) Complexes

General

All solvents used for spectrometric measurements have the quality appropriate for spectrometric measurements. Pt(CN)₂, dppb (1,2-bis(diphenylphosphino)benzene) and binap (1,1′-binaphthyl) and bathophen (4,7-diphenyl-1,10-phenanthroline) and tert-Bu₂ bpy (4,4′-tert-butyl-2,2′-bipyridine) are commercially available and are used without further purification.

a) [Pt(dppb)(CN)₂]

A mixture of Pt(CN)₂ (0.76 g, 3 mmol) and dppb (1.38 g, 3 mmol) is dissolved in 70 ml of dimethylformamide and refluxed for 6 hours. A white pulverulent precipitate is slowly formed. The precipitate is collected by filtration, washed with diethyl ether and dried over silica gel under reduced pressure. The white material obtained is purified by re-crystallization from dichloroethane/diethyl ether and obtained in a yield of 0.92 g (43%).

Elemental analysis: C, 55.42; H, 3.49; N, 4.04; found: C, 55.06; H, 3.60; N, 3.94.

b) [Pt(binap)(CN)₂]×H₂O

A mixture of Pt(CN)₂ (0.25 g, 1 mmol) and binap (0.63 g, 1 mmol) in 40 ml of dimethylformamide is refluxed for 20 hours. After filtration of the mixture, diethyl ether is added to the solution obtained. This results in precipitation of a light-yellow powder. The yellow powder is collected by filtration, washed with diethyl ether and dried over silica gel under reduced pressure. The light-yellow material obtained is recrystallized from dichloromethane/diethyl ether, giving 0.58 g (65%) of the desired product.

Elemental analysis: C, 62.23; H, 3.86; N, 3.16; found: C, 62.68; H, 3.90; N, 3.07.

c) [Pt(bathophen)(CN)₂×H₂O]

The preparation of [Pt(bathophen)(CN)₂×H₂O] is disclosed in J. Am. Chem. Soc. 112 (1990) 5625-5627.

d) [Pt(4,4′-Bu₂ bpy)(CN)₂]*
* The preparation was carried out by a method analogous to that for [Pt(CN)₂(5,5′-Me₂ bpy)] in Che, C.-M., Wan, K.-T., He, L.-Y., Poon, C.-K., Yam, V. W.-W., J. Chem. Soc., Chem. Commun. 1989, 943.

0.99 g (4.0 mmol) of Pt(CN)₂ and 1.10 g (4.0 mmol) of 4,4′-di-tert-butyl-2,2′-dipyridyl (4,4′-Bu₂ bpy) were refluxed in 70 ml DMF for 84 hours. This resulted in a pale yellow solution with a greenish precipitate. This was filtered off and the filtrate was admixed with diethyl ether. A fine pale yellow precipitate was formed and this was filtered off with suction, washed with diethyl ether and dried over silica gel. Yield: 0.94 g (46% of theory). The substance obtained was recrystallized from DMF/diethyl ether. C₂₀H₂₄N₄Pt (515.53): calc. C, 46.76; H, 4.69; N, 10.87; found C, 45.34; H, 4.54; N, 11.18. MS(ESI): 515 (77%), 516 (MH⁺, 100%), 517 (82%)

1. Organic light-emitting diodes (OLED) comprising uncharged platinum(II) complexes selected from the group consisting of platinum(II)-phosphine complexes of the formula (I), 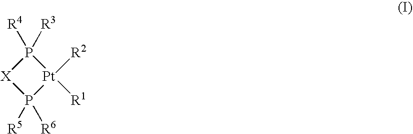
platinum(II)-bathophen complexes of the formula (II) 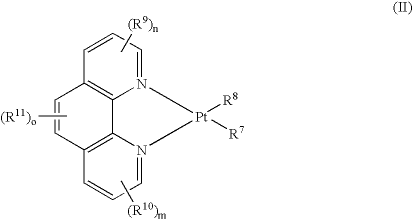
and
platinum(II)-bipyridyl complexes of the formula (III) 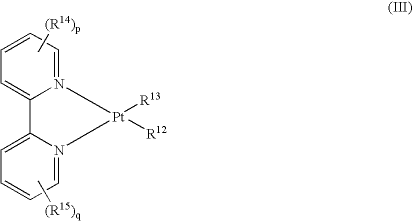
where the symbols have the following meanings:
R¹, R², R⁷, R⁸, R¹², R¹³ are each, independently of one another, CN, acetylide, thiocyanate or isocyanate;
R³, R⁴, R⁵, R⁶, R⁹, R¹⁰, R¹⁴, R¹⁵ are each, independently of one another, an aryl, alkyl, heteroaryl or alkenyl group;
X is an arylene group or a heteroarylene group;
o is from 0 to 2;
p, q are each, independently of one another, from 0 to 4;
n, m are each, independently of one another, from 0 to 3;
as emitter molecules.

2. Organic light-emitting diodes according to claim 1, wherein, in the platinum(II)-phosphine complexes of the formula I, R¹ and R² are each CN or acetylide, preferably CN, and R³, R⁴, R⁵ and R⁶ are each an aryl radical, preferably unsubstituted phenyl, and X is selected from the group consisting of a phenylene group which is linked in the 1 and 2 positions to, in each case, one of the two P atoms in the formula I and is particularly preferably unsubstituted, a naphthalenediyl group which is linked in the 2 and 3 positions or 4 and 5 positions to, in each case, one of the two P atoms in the formula I and is particularly preferably unsubstituted, a phenanthrenediyl group which is linked in the 2 and 3 positions or in the 4 and 5 positions to, in each case, one of the two P atoms in the formula I and is particularly preferably unsubstituted, a 1,1′-biphenylene group which is linked in the 2 and 2′ positions to, in each case, one of the two P atoms in the formula I and is particularly preferably unsubstituted, a 1,1′-binaphthylene group which is linked in the 2 and 2′ positions to, in each case, one of the two P atoms in the formula I and is particularly preferably unsubstituted, and X is particularly preferably selected from among a phenylene group which is linked in the 1 and 2 positions to, in each case, one of the two P atoms in the formula I and is unsubstituted and a 1,1′-binaphthylene group which is linked in the 2 and 2′ positions to, in each case, one of the two P atoms in the formula I and is unsubstituted.

3. Organic light-emitting diodes according to claim 1, wherein, in the platinum(II) complexes of the formula II and the platinum(II) complexes of the formula III, R⁷, R⁸, R¹² and R¹³ are each CN, m, n, p, q are each 0 or 1 and o is 0, and, when m, n=1, R⁹ and R¹⁰ are each unsubstituted phenyl and, when p, q=1, R¹⁴ and R¹⁵ are each tert-Bu.

4. Organic light-emitting diodes according to claim 1, wherein the platinum(II) complexes are mononuclear complexes.

5. Organic light-emitting diodes comprising platinum(II) complexes according to claim 1 as light-emitting layer.

6. A light-emitting layer comprising at least one platinum(II) complex according to claim 1 as emitter molecule.

7. A light-emitting layer consisting of at least one platinum(II) complex according to claim 1 as emitter molecule.

8. An OLED comprising a light-emitting layer according to claim 6.

9. A device selected from the group consisting of stationary VDUs such as VDUs of computers, televisions, VDUs in printers, kitchen appliances and advertising placards, lighting, information signs and mobile VDUs such as VDUs in mobile telephones, laptops, vehicles and destination displays in buses and trains comprising an OLED according to claim 8.

10. An OLED comprising a light-emitting layer according to claim 7.

11. A device selected from the group consisting of stationary VDUs such as VDUs of computers, televisions, VDUs in printers, kitchen appliances and advertising placards, lighting, information signs and mobile VDUs such as VDUs in mobile telephones, laptops, vehicles and destination displays in buses and trains comprising an OLED according to claim 10.

12. A device selected from the group consisting of stationary VDUs such as VDUs of computers, televisions, VDUs in printers, kitchen appliances and advertising placards, lighting, information signs and mobile VDUs such as VDUs in mobile telephones, laptops, vehicles and destination displays in buses and trains comprising an OLED according to claim 1.
